(19) United States
(12) Patent Application Publication
(10) Pub. No.: US 2022/0376612 A1
(43) Pub. Date: Nov. 24, 2022

(54) SNUBBER CIRCUIT

(71) Applicant: Hewlett-Packard Development Company, L.P., Spring, TX (US)

(72) Inventors: Juan Luis Lopez Rodriguez, Sant Cugat del Valles (ES); Sergio Alejandro Lopez Ramos, Sant Cugat del Valles (ES); Santiago Sanz Ananos, Sant Cugat del Valles (ES); Antonio Rodriguez Avila, Sant Cugat del Valles (ES); Jose Ma. Rio Doval, Sant Cugat del Valles (ES)

(21) Appl. No.: 17/765,155

(22) PCT Filed: Nov. 7, 2019
(86) PCT No.: PCT/US2019/060310

§ 371 Date: Mar. 30, 2022

(51) Int. Cl. H02M 1/34; H02M 7/06; H05B 1/02; H03K 17/06

(52) U.S. Cl. CPC H02M 1/342; H02M 7/06; H05B 1/02; H03K 17/063

(57) ABSTRACT

There is described a snubber circuit comprising an electronic switch. The circuit includes an impedance network comprising reactive circuit elements to smooth energy transients if the electronic switch is turned off and if the switch is turned on. A resistive element dissipates energy released by at least one of the reactive circuit elements. The resistive element is of a load to be driven using the electronic switch. A power supply unit may include the described snubber circuit.

### BACKGROUND

Systems that control the supply of electrical power using switching topologies often use semiconductor transistors, e.g. a MOSFET, that change the conduction state (on-off) in a short time. On the one hand, fast change is useful because it minimises the time that the switch is heating itself. On the other hand, fast change causes a rapid change of voltage (dV/dt) and current (dl/dt), perturbs the electromagnetic field and results in undesired radiation of electromagnetic (EM) energy. Dissipative snubber circuits may be added to power circuitry so that the dV/dt and dl/dt may be reduced and the switching loss and stress diverted to the components of the snubber circuit.

### BRIEF DESCRIPTION OF THE DRAWINGS

Various features and advantages of certain examples will be apparent from the detailed description which follows, taken in conjunction with the accompanying drawings, which together illustrate, by way of example, a number of features, and wherein:

FIG. 1 is a circuit diagram showing a snubber circuit according to an example;

FIG. 2 is a circuit diagram illustrating current loops of the circuit of FIG. 1 when a transistor is turned on according to an example;

FIG. 3 is a circuit diagram illustrating current loops of the circuit of FIG. 1 when a transistor is turned off according to an example;

FIGS. 4a and 4b are plots of load current (I_{Load}) versus time for the circuit of FIG. 1 highlighting the behaviour when the switch is turned on and off respectively;

FIG. 5 is a schematic showing components of a power supply circuit according to an example;

### DETAILED DESCRIPTION

In the following description, for purposes of explanation, numerous specific details of certain examples are set forth. Reference in the specification to “an example” or similar language means that a particular feature, structure, or characteristic described in connection with the example is included in at least that one example, but not necessarily in other examples.

In electrical power control circuits that have topologies using switching transistors. The amount of radiated energy is proportional to the physical dimension of circuit nodes exposed to high voltage transients dV/dt or current loops exposed to high current transients dl/dt. This suggests one way to reduce radiation is to confine the fast changes to a small volume and to avoid physically long conductors and wide current loops.

In the practice, however, it is not feasible to confine all the elements of a system into such a small volume. For instance, in heating applications there are resistive elements that should be located close to the area to be heated, whereas the controlling system should be in a different location away from the heating element.

Then, if confining all elements to a single point is not practical, we can use an alternative: to separate “fast” from “slow” systems. Fast systems, like the switch inside the power controller, should be in a confined volume. Slow systems, like the heating resistor, could be far away. The mentioned separation requires additional reactive circuit components (such as capacitors or inductors) located in the confined volume. These circuit components store and dissipate electrical energy. The circuits commonly known as “snubbers” or “snubber circuits” are sets of such circuit components.

The simplest snubbers dissipate energy stored into its own local resistor or resistors which are distinct from the load which is separately connected across the output terminals of the snubber circuit. As the controlled power gets bigger, the power (i.e. energy) to be dissipated also grows. For instance, capacitive snubbers dissipate a power that grows with the square of voltage that is controlled. This is an obstacle for scaling such snubbers into high power applications. More elaborate snubbers do not have local dissipation resistors at all and merely bounce the energy between reactive components in the circuit.

An example described here is applicable to power controllers used for resistive heating applications. In an example, the snubber circuit comprises an electronic switch, an impedance network and a resistive element. The impedance network includes reactive circuit elements (e.g. a combination of capacitors and inductors) to smooth energy transients both when the switch is turned off and when the switch is turned on. Rather than using a local resistive element for dissipation, the resistive element is of a load that is driven with electrical power using the electronic switch and it is thus an element of the load itself that dissipates energy (stored and) released by a reactive element or reactive elements of the snubber circuit. The electronic switch may be a transistor such as a MOSFET, or other three terminal active switching element for use in a power circuit.

According to an example, a snubber is thus provided that blocks both fast dV/dt and dl/dt transients in both turn-on and turn-off events. According to an example, the snubber circuit has no dissipation resistors inside, so it is scalable to higher powers. A heating resistor, forming a component of load, located far from away from the snubber is leveraged as dissipation resistor. The snubber profiles the voltages and currents in order to avoid any fast dV/dt or dl/dt outside of the confined volume.

According to examples, the components of the impedance network have the following functions:
1) Components that store electrical energy in the form of magnetic and electrical fields. They are inductors and capacitors.
   a) In an example, some avoid the propagation of fast dV/dt and dl/dt. They are capacitors in parallel with the transistor, and inductor in series.
   b) In an example, some cooperate with the previous components and have the role of transferring the energy from near the transistor to the dissipative load.

In an example, the snubber includes components that switch passively in order to transfer electrical power. In other words, to provide respective current paths between the reactive elements to smooth the energy transients when the electronic switch is turned off and when the switch is turned on, and to dissipate energy from the reactive elements through the load. In an example, the passive switching components (elements) consist of diodes that are indirectly commanded by the main switching transistor.

The snubber circuit further includes a component or components that dissipate electrical power (e.g. released by the reactive circuit elements) into heat. The component that dissipates energy from the reactive components is a resistive element of a load. In an example, the load is a heating element already used for heating purposes and thus, the dissipation is used to generate heat at the heating element.

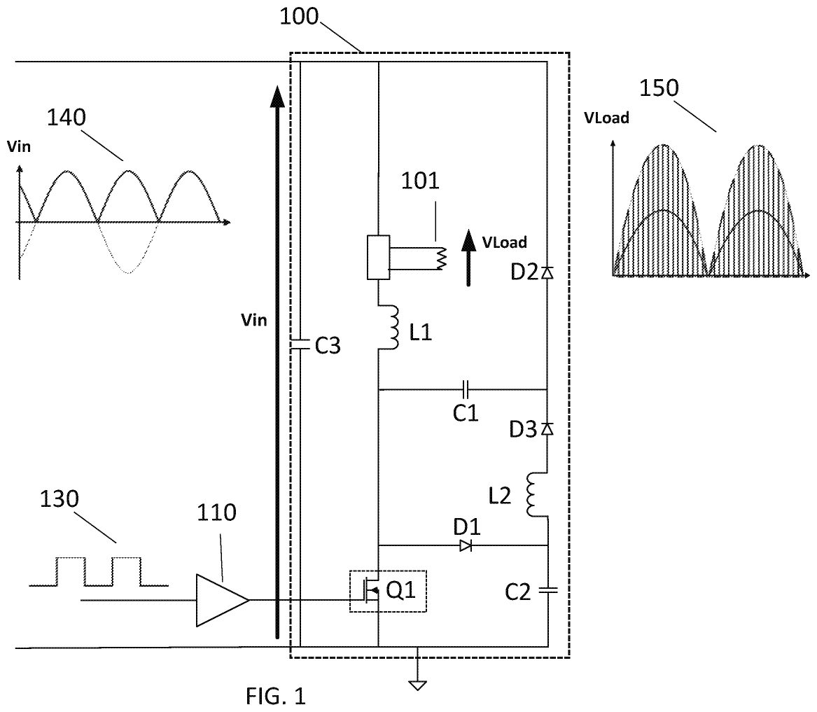

FIG. 1 is a circuit diagram of a system that includes a snubber circuit 100. In this example, the system includes a driver 110 to drive a transistor Q1 in the snubber circuit. In this example, a rectified sinusoidal DC voltage 140 is provided as a voltage input (Vᵢₙ) to the circuit 100. The driver 110 is operable to drive the switch according to a pulse train signal with a predetermined frequency and duty cycle to provide a desired chopped output signal 150 (Mead) across a load 101 of the snubber circuit 100. The load may be a resistive element or include at least one resistive element for dissipating energy from the circuit 100. For example, the load may be a heating element. The heating element may be a component of a rendering device such as a printer according to an example.

The snubber circuit 100 includes an inductor L1 connected to the drain of the switching power MOSFET Q1. The inductor L1 is to store energy supplied by the input signal 140 during turn-on of the switch to smooth a current transient (dl/dt). A capacitor C2 (and in an example, C1 and C3 also) is provided to receive energy released from the inductor L1 and to discharge energy to the load. The discharge of energy from C2 to the load is via an inductor L2 and capacitor C1. The capacitor C1 is arranged to receive energy from the capacitor C2 during turn-on of the switch Q1 and discharge energy through the load during turn-off of the switch Q1. The inductor L2 slows the transfer of energy between the first and second capacitors C1, C2. A further capacitor C3 is connected from the supply rail to ground in order to receive excess energy which cannot be stored at the first and second capacitors. The capacitor C3 may source energy to the load initially when the transistor Q1 is turned on. The capacitors C1 and C2 further act to smooth voltage transients dV/dt during turn on and turn off of the switch Q1. In an example, C1=68 nF, C2=68 nF, C3=5.6 μF, L1=4.3 pH and L2=10 pH. According to an example, where the load 101 is a heating element (e.g. a heater) it may be represented as an 6 pH inductor with a series resistance of 11Ω and parasitic capacitance (2000 pF). Diodes D1, D2 and D3 define respective current paths (loops) by blocking or allowing conduction depending on the status of the transistor Q1 and/or biasing conditions at nodes in the circuit. The diodes although respective current paths to be defined for transferring energy between the reactive components to smooth the energy transients at turn-on and turn-off and to dissipate energy through the load 101.

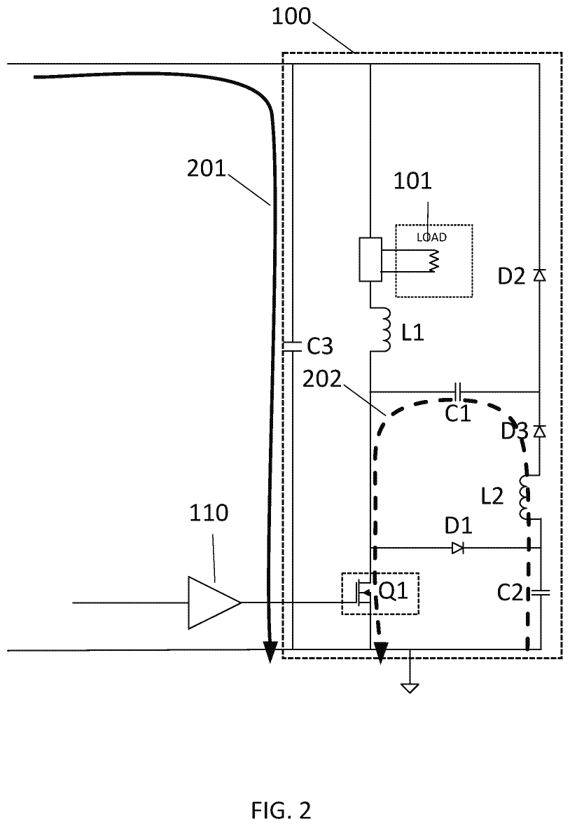

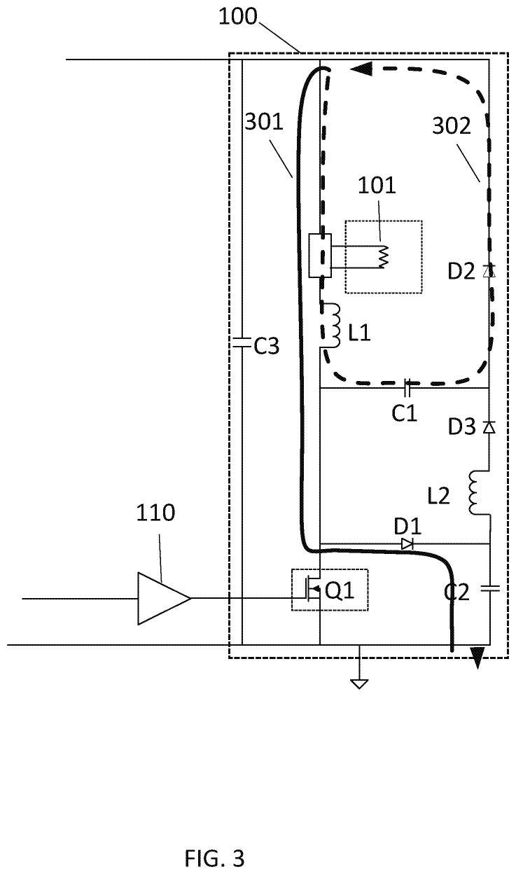

A detailed description of operation of the circuit 100 will now be explained in more detail with reference to FIGS. 2 and 3.

FIG. 2 illustrates the current loops in the circuit 100 when the MOSFET Q1 is switched on. The initial conditions before MOSFET Q1 turns on are assumed to be that the energy in C1, L1 and L2 is zero and energy in C2 and C3 is at a maximum.

When the MOSFET Q1 turns on, current begins to flow through the transistor Q1 and into the load 101 through path 201 thereby charging energy into L1. L1 blocks the turn on transient and consequently makes dl/dt smoother. Initially, just after turn-on, it is C3 that sources energy into load 101 and inductor L1. At the same time, capacitor C2 begins to transfer energy to inductor L2 and capacitor C1 (and eventually, where there is no capacity left in C1 and C2, to C3), i.e. via current path 202 defined by conduction through diode D3 and Q1 which is in its ‘ON’ state.

When all the energy in C2 is transferred to L2/C1, two diodes (D1 and the parasitic diode in Q1) are blocking conduction and thus ensure that C2 stays at zero energy (voltage) for the remainder of the turn-on cycle.

D1 and D3 block until the end of the turn-on cycle. However, if L2 still has some energy, this remaining energy is transferred to C1 via D1 and D3.

When all energy in L2 is transferred to C1, D3 and D1 are blocking conduction and ensure that L2 energy stays at zero for the remaining of the cycle.

If for any reason (for instance, C1 capacitance being lower than expected) the voltage in node 2 would exceed the supply voltage, then excess energy would be transferred to C3 through D2, thus ensuring the voltage in C1 never exceeds the supply voltage Vᵢₙ.

After this sequence, the energy in L1 is at a maximum, the energy in C2 and L2 is zero, and the energy in C1 is same (or less) than it was in C2. D1, D2 and D3 are blocked. This condition remains until the next cycle begins (i.e. with MOSFET turning off).

There is a minimum ON time to let the full energy transfer process to take place, this minimum ON time in an example is approximately 2 μs.

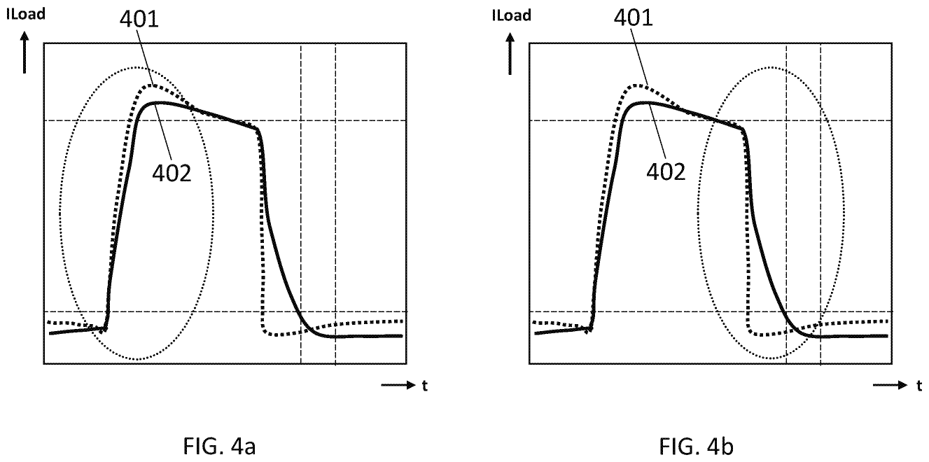

FIGS. 4a and 4b shows a plot of current through the load I_{Load} (and thus through the transistor Q1) against time t during a cycle in which the transistor Q1 is first turned on and then turned off. A plot shows the response with 402 and without 401 the snubber circuit. As can be seen by the highlighted rising edge in FIG. 4a, the gradient of I_{Load} is reduced, as is the overshoot, thereby reducing the current transient dI_{Load}/dt at turn-on. Similar smoothing behaviour during turn-on (although not plotted) can be observed in the dV/dt of the voltage at the drain of the transistor Q1 due to the snubbing action of the capacitors C1 and C2.

FIG. 3 shows the current paths (loops) that are defined (operate) when the MOSFET Q1 is turned off. When the power MOSFET Q1 turns off, the energy in L1 begins to transfer to C1, C2 and C3. Following the turn-on cycle, C1 and C3 are initially charged with opposite sign (voltage), now their stored energy drops. C2 was initially discharged following the turn-on cycle, now its stored energy rises via path 301.

At this stage the energy from C1 is dissipated into the load 101 via C1 current in path 302. Accordingly, energy in the circuit is stored in reactive components, and is not converted into heat in the snubber itself, but transferred to the load, and if, for example, the load is a heater, converted into heat there. Repeated turn-on and turn-off cycles cause the energy to bounce (transfer) from L1 to C2, from C2 to C1 and then dissipate via C1 current through the load. Accordingly, the energy in the circuit is not stored and converted into hear but instead, e.g. where the load is a heater, radiated into space. If the energy stored in L1 fits into C1 and C2, both D1 and D2 block until the end of this cycle. Otherwise, D2 redirects the excess of energy into C3 (path not shown).

After this sequence, energy in L1 is zero, in 02 is maximum, in C1 and L2 is zero. D1, D2 and D3 are blocking conduction. This condition remains until the next cycle begins (with MOSFET turning on).

In an example, the minimum OFF time for this energy transfer process is 5 μs, almost double than the than the ON minimum time due to the fact that both C1 and C2 are now connected in parallel.

The highlighted area in FIG. 4b shows a comparison of the current through the load I_{Load} (and thus transistor Q1) against time t, with 402 and without 401 the snubbing action of the circuit 100 at turn-off. As can be seen, I_{Load} falls off gently when the circuit 100 is used 402 which can be contrasted with abrupt stepped transition from high to low without 401. Accordingly, the snubbing action greatly reduces the current transient dI_{Load}/dt at turn-off of the transistor Q1. Similar smoothing behaviour during turn-off (although not plotted) can be observed in the voltage transient dV/dt at the drain of the transistor Q1 due to the snubbing action of the capacitors C1 and C2.

During turn-on of the MOSFET Q1 the drain node drops in voltage rapidly making it the worst E_{field} emitter of the circuit 100. The conduction path and elements from the drain node of the MOSFET Q1 through C1 and up to (bot not including) diode D2 should be minimised in area if possible, in addition to the conduction path from the drain of MOSFET Q1 up to (but not including) diode D1. In the case of D1 and D2 having significant reverse conduction, C2 and C3 may also need to be considered as relevant components with respect to E_{field} emission and thus efforts should be made to minimise their area. During turn-off of the MOSFET Q1, current through D1, C2, C1, D2 and C3 rises rapidly, making this part the worst B_{field} emitter. Accordingly, in an example, loop area should be minimised in these parts of the layout in order to reduce B_{field} emissions.

The snubber circuit 100 may have application in devices such as printers that use heating elements. For example, in Latex printers, it is necessary to apply heat to the ink to evaporate the water and cure the Latex.

The heat is applied using resistive loads and fans. The fans absolve part of the energy of the heating elements and then by convection the air is transmitting the heat to the ink and the substrate. Once the ink is dried and all the water is evaporated, the energy is absorbed by the Latex particles and create a film. Once the film is created, the job is considered as cured.

This process is to ensure a good quality of the plot the get the right color and durability. To make sure that the jobs are properly cured, it is mandatory control the amount of power we are providing to the heating elements. For controlling the power applied to the heating elements, a switched power supply is desirable.

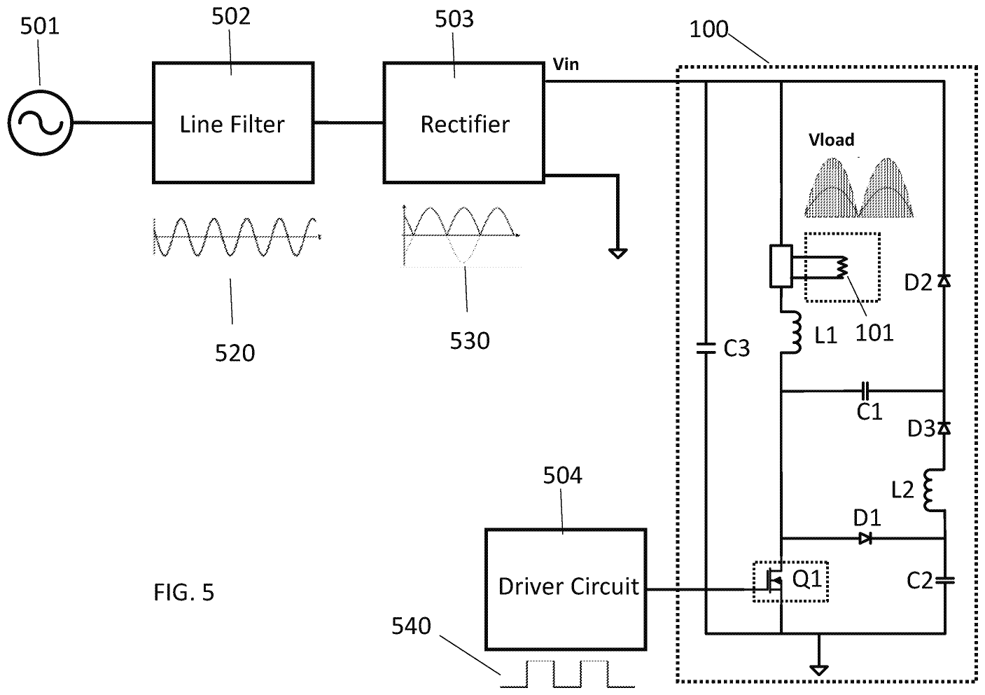

FIG. 5 shows a schematic diagram of a switched power supply 500 according to an example. The switched power supply uses the above described snubber circuit 100 as the power driver. This may be used, for example, to achieve a low-cost power supply compliant with all current regulatory standards to include in a Latex printer. The power supply circuit 500 includes an AC line supply 501 which provides and AC signal to a line filter 502. The line filter 502 is configured to remove unwanted frequencies present in the AC supply frequency due to noise or other sources of distortion. The filter may be a common mode filter, according to an example. The filtered signal 520 from the line filter 502 is provided to a rectifier 503 which rectifies the AC signal to a DC signal. For example, a diode bridge may be used to provide full wave rectification of the AC single. Other types of rectifier circuit are possible, however. The rectified signal 530 is provided by the rectifier 503 to the input of snubber circuit 100 as the input signal Vᵢₙ. A driver circuit 504 is provided which may be arranged to provide a pulse train signal to drive the power MOSFET Q1 of the snubber circuit. Although not shown, a further filter stage may be provided between the rectifier 503 and the snubber circuit 100. This filter stage may be to avoid noise at the input and also to maintain energy for the output load. According to an example a differential mode filter may used.

Accordingly, the supply according to FIG. 5 may be an AC/AC switched power supply designed to adjust the power delivered to a resistive load transferring a minimum energy into the load. Thus, a very low cost switched supply is provided that can be built using standard catalog components compared to other AC/AC power supply topologies.

The power supply 500 may be to supply power to a printer or other rendering device. For example, when applied to Latex printers that require to dry and cure the ink in a controlled way or other rendering devices that use heating elements a low cost and efficient solution may be provided. This may be the case or printers where ink needs to be cured and a regulated power supply is mandatory to control the amount of power delivered to the system. Regulated power supplies can be found for driving drying and curing subsystem as the ones found in Latex printers.

While the method, apparatus and related aspects have been described with reference to certain examples, various modifications, changes, omissions, and substitutions can be made without departing from the spirit of the present disclosure. In particular, a feature or block from one example may be combined with or substituted by a feature/block of another example.

The word “comprising” does not exclude the presence of elements other than those listed in a claim, “a” or “an” does not exclude a plurality, and a single processor or other unit may fulfil the functions of several units recited in the claims.

The features of any dependent claim may be combined with the features of any of the independent claims or other dependent claims.

1. A snubber circuit comprising:
an electronic switch;
an impedance network comprising reactive circuit elements to smooth energy transients if the electronic switch is turned on and if the switch is turned off; and
a resistive element to dissipate energy released by at least one of the reactive circuit elements, wherein the resistive element is of a load to be driven using the electronic switch.

2. A snubber circuit according to claim 1, wherein the reactive circuit elements comprise an inductor (L1) to store energy from a supply during turn-on of the switch to smooth a current transient.

3. A snubber circuit according to claim 2, comprising a first capacitor (C2) to smooth a voltage transient, the first capacitor (C2) to receive energy from the inductor (L1) and discharge energy stored at the first capacitor (C2) to the load.

4. A snubber circuit according to claim 3 comprising a second capacitor (C1), wherein the first capacitor (C2) is configured to, during turn-on of the switch, receive energy from the second capacitor (C1) and to, during turn-off of the switch, discharge energy through the load.

5. A snubber circuit according to claim 4, comprising a second inductor (L2) to slow the transfer of energy between the first capacitor (C2) and the second capacitor (C1).

6. A snubber circuit according to claim 5, comprising a third capacitor (C3) to receive excess energy unable to be stored at the first and second capacitors (C1, C2), and to source energy to the load during turn-on of the switch.

7. A snubber circuit according to claim 1, wherein the wherein the impedance network comprises passive switching elements to provide respective current paths between the reactive elements to smooth the energy transients when the electronic switch is turned off and when the switch is turned on, and to dissipate energy from the reactive elements through the load.

8. A snubber circuit according to claim 7, wherein the passive switching elements are diodes.

9. A snubber circuit according to claim 1, wherein the electronic switch comprises a MOSFET.

10. A snubber circuit according to claim 1, wherein the load comprises a heating element.

11. A snubber circuit according to claim 10, wherein the heating element comprises a component of a rendering apparatus.

12. A power supply circuit comprising a snubber circuit, the snubber circuit comprising:
an electronic switch;
an impedance network comprising reactive circuit elements to smooth energy transients if the electronic switch is turned on and if the switch is turned off; and
a resistive element to dissipate energy released by at least one of the reactive circuit elements,
wherein the resistive element is of a load to be driven using the electronic switch.

13. A power supply circuit according to claim 12, further comprising a line filter for filtering high frequency components from an AC supply.

14. A power supply circuit according to claim 12, further comprising a rectifier for rectifying an AC signal

15. A power supply circuit according to claim 12, further comprising a drive circuit for driving the electronic switch to chop a signal supplied to the load.
